(19) United States
(12) Patent Application Publication
(10) Pub. No.: US 2007/0264816 A1
(43) Pub. Date: Nov. 15, 2007

(54) Copper alloy layer for integrated circuit interconnects

(76) Inventors: Adrien R. Lavoie, Beaverton, OR (US); Juan E. Dominguez, Hillsboro, OR (US); John J. Plombon, Portland, OR (US); Joseph H. Han, San Jose, CA (US); Harsono S. Simka, Saratoga, CA (US)

Correspondence Address: INTEL CORPORATION;c/o INTELLEVATE, LLC, P.O. BOX 52050, MINNEAPOLIS, MN, 55402, US

(21) Appl. No.: 11/434,450

(22) Filed: May 12, 2006

(51) Int. Cl. H01L 21/4763

(52) U.S. Cl. 438/618

(57) ABSTRACT

A method for forming a metal interconnect comprises providing a dielectric layer on a substrate within a reaction chamber where the dielectric layer includes a trench, conformally depositing a barrier layer on the dielectric layer within the trench, conformally depositing a Cu—Al alloy layer on the barrier layer within the trench, depositing a copper layer to fill the trench, and planarizing the copper layer to form the metal interconnect. The Cu—Al alloy layer may be formed by sequential ALD or CVD deposition of an aluminum layer and a copper layer followed by an annealing process. Alternately, the Cu—Al alloy layer may be formed in-situ by co-pulsing the aluminum and copper precursors.

### BACKGROUND

In the manufacture of integrated circuits, copper interconnects are generally formed on a semiconductor substrate using a copper dual damascene process. Such a process begins with a trench being etched into a dielectric layer and filled with a barrier layer, an adhesion layer, and a seed layer. A physical vapor deposition (PVD) process, such as a sputtering process, may be used to deposit a tantalum nitride (TaN) barrier layer and a tantalum (Ta) or ruthenium (Ru) adhesion layer (i.e., a TaN/Ta or TaN/Ru stack) into the trench. The TaN barrier layer prevents copper from diffusing into the underlying dielectric layer. The Ta or Ru adhesion layer is required because the subsequently deposited metals do not readily nucleate on the TaN barrier layer. This may be followed by a PVD sputter process to deposit a copper seed layer into the trench. An electroplating process is then used to fill the trench with copper metal to form the interconnect.

As device dimensions scale down, the aspect ratio of the trench becomes more aggressive as the trench becomes narrower. This gives rise to issues such as trench overhang during the copper seed deposition and plating processes, leading to pinched-off trench openings and inadequate electroplating gapfill. Additionally, as trenches decrease in size, the ratio of barrier to copper in the overall interconnect structure increases, thereby increasing the electrical line resistance and RC delay of the interconnect.

One approach to addressing these issues is to reduce the thickness of the TaN/Ta or TaN/Ru stack, which widens the available gap for subsequent metallization and increases the final copper volume fraction. Unfortunately, this is often limited by the non-conformal characteristic of PVD deposition techniques. Accordingly, alternative techniques for reducing the thickness of the barrier and adhesion layer are needed.

### BRIEF DESCRIPTION OF THE DRAWINGS

FIGS. 1A to 1E illustrate a conventional damascene process for forming metal interconnects.

FIG. 2 is a process for forming a metal interconnect in accordance with an implementation of the invention.

FIGS. 3A to 3G illustrate structures that are formed when the process of FIG. 2 is carried out.

FIG. 4 is a process for forming a metal interconnect in accordance with another implementation of the invention.

FIGS. 5A to 5C illustrate structures that are formed when the process of FIG. 4 is carried out.

### DETAILED DESCRIPTION

Described herein are systems and methods of forming a metal interconnect for an integrated circuit. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention; however, the order of description should not be construed to imply that these operations are necessarily order dependent. In particular, these operations need not be performed in the order of presentation.

Implementations of the invention enable the formation of copper interconnects with lower electrical resistance and a lower likelihood of defect formation relative to conventional copper interconnects. The copper interconnects of the invention are formed without the use of a tantalum (Ta) or ruthenium (Ru) adhesion layer between the tantalum nitride (TaN) barrier layer and the metal layer. Eliminating the Ta or Ru adhesion layer widens the available gap for metallization, thereby reducing the likelihood of trench overhang that can lead to void formation. Eliminating the adhesion layer also increases the final copper volume fraction, thereby decreasing the electrical line resistance of the interconnect. In implementations of the invention, in lieu of a Ta or Ru adhesion layer, a copper-aluminum (Cu—Al) alloy layer is formed on the barrier layer that facilitates metal deposition directly onto the barrier layer using conventional vapor deposition techniques, such as atomic layer deposition (ALD) or chemical vapor deposition (CVD).

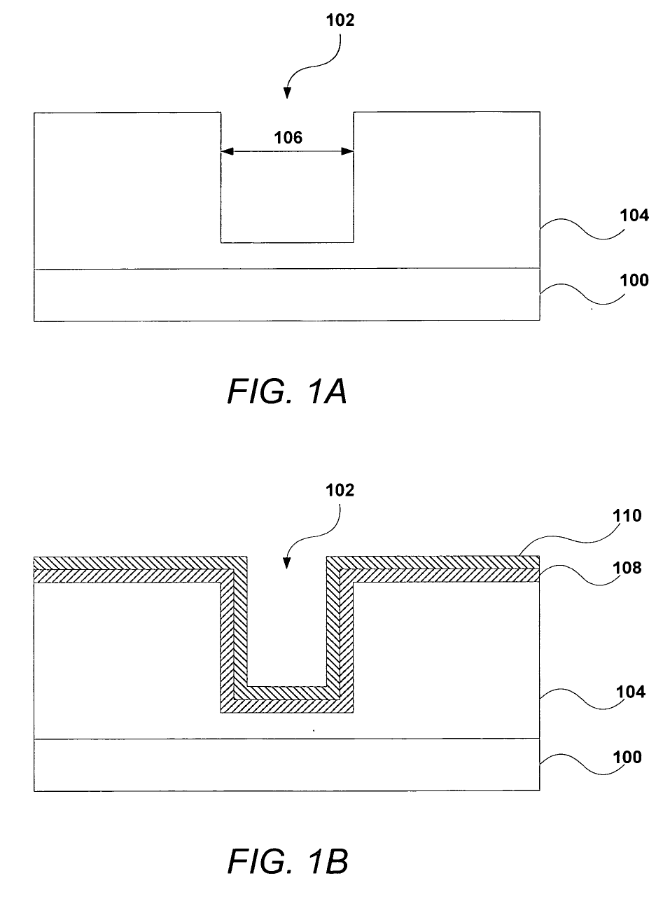

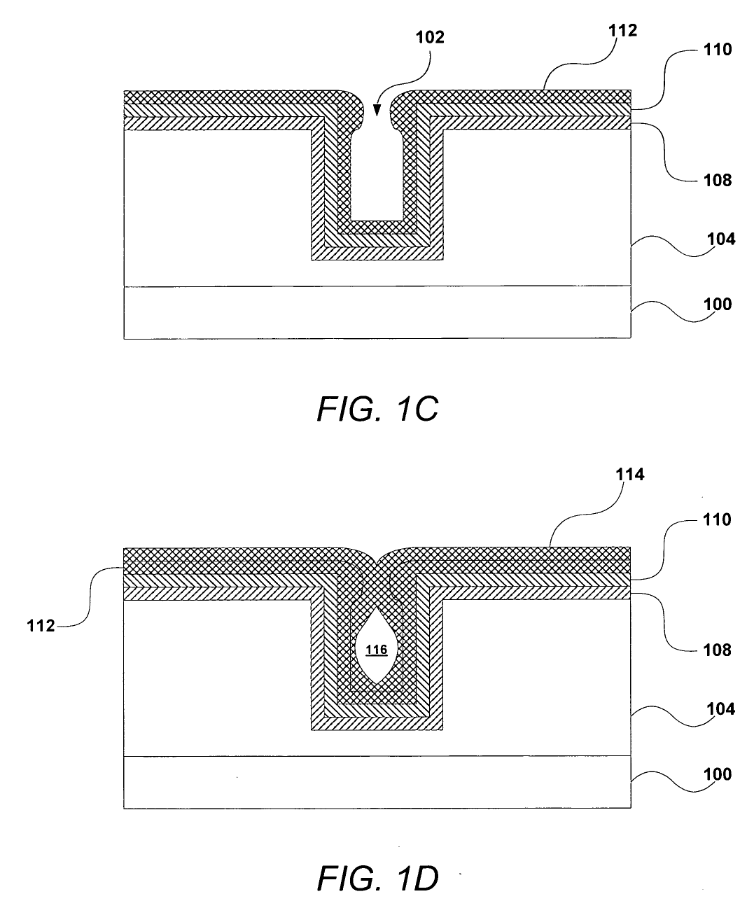

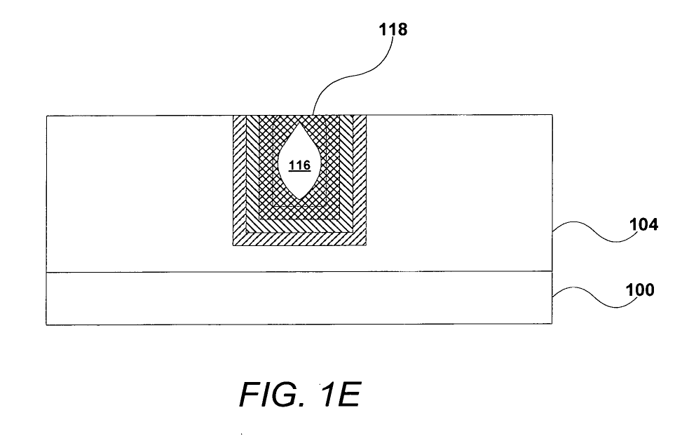

For reference, FIGS. 1A to 1E illustrate a conventional damascene process for forming copper interconnects on a semiconductor wafer. FIG. 1A illustrates a substrate 100, such as a semiconductor wafer, that includes a trench 102 that has been etched into a dielectric layer 104. The trench 102 includes a gap 106 through which metal may enter during metallization processes.

FIG. 1B illustrates the trench 102 after a conventional barrier layer 108 and a conventional adhesion layer 110 have been deposited. The barrier layer 108 prevents copper metal from diffusing into the dielectric layer 104. The adhesion layer 110 enables copper metal to become deposited onto the barrier layer 108. The barrier layer 108 is generally formed using a material such as tantalum nitride (TaN) and is deposited using a PVD process. The barrier layer 108 may be around 0.5 nanometers (nm) to 10 nm thick, although it is generally around 5 nm thick. The adhesion layer 110 is generally formed using a metal such as tantalum (Ta) or ruthenium (Ru) and is also deposited using a PVD process. The adhesion layer 110 is generally around 2 nm to 10 nm thick.

After the adhesion layer 110 is formed, the conventional damascene process of FIG. 1 uses two independent deposition processes to fill the trench 102 with copper metal. The first deposition process is a PVD process that forms a non-conformal copper seed layer. The second deposition process is a plating process, such as an electroplating (EP) process or an electroless plating (EL) process, which deposits a bulk copper layer to fill the trench 102.

FIG. 1C illustrates the trench 102 after a conventional copper seed layer 112 has been deposited onto the adhesion layer 110 using a PVD process. The copper seed layer 112 enables or catalyzes a subsequent plating process to fill the interconnect with copper metal. FIG. 1D illustrates the trench 102 after an EP or EL copper deposition process has been carried out. Copper metal 114 enters the trench through the gap 106 where, due to the narrow width of the gap 106, issues such as trench overhang and pinching off of the trench opening may occur that lead to defects. For instance, as shown in FIG. 1D, trench overhang may occur that pinches off the opening of the trench 102, creating a void 116 that will remain in the final interconnect structure.

FIG. 1E illustrates the trench 102 after a chemical mechanical polishing (CMP) process is used to planarize the deposited copper metal 114. The CMP results in the formation of a metal interconnect 118. As shown, the metal interconnect 118 includes the void 116 that was formed when the available gap 106 was too narrow and the resulting trench overhang pinched off the trench opening. Furthermore, a substantial portion of the metal interconnect 118 comprises Ta and/or Ru from the adhesion layer 110 and the barrier layer 108.

To overcome the above-mentioned issues with conventional metal interconnects, implementations of the invention provide methods of depositing copper metal directly onto a barrier layer, such as a TaN barrier layer, without the need for a conventional Ta or Ru adhesion layer. Directly depositing copper metal onto the barrier layer allows a higher percentage of the metal interconnect to be formed from copper, thereby decreasing the electrical resistance of the metal interconnect. Elimination of the Ta or Ru adhesion layer also widens the trench gap that is available for metallization, allowing the plated metal to more easily enter the trench and substantially reducing or eliminating the occurrence of trench overhang. For instance, since the adhesion layer is generally around 2 nm to 10 nm thick, elimination of the adhesion layer opens the available gap by approximately 4 nm to 20 nm.

In accordance with implementations of the invention, a copper-aluminum (Cu—Al) alloy is generated on the barrier layer in lieu of a conventional adhesion layer. The Cu—Al alloy layer places copper metal directly in contact with the barrier layer, which increases the overall percentage of copper metal in the interconnect structure to increase its current carrying capacity. Furthermore, the Cu—Al alloy layer provides a surface upon which additional copper metal may be deposited and presents improved electromigration resistance benefits.

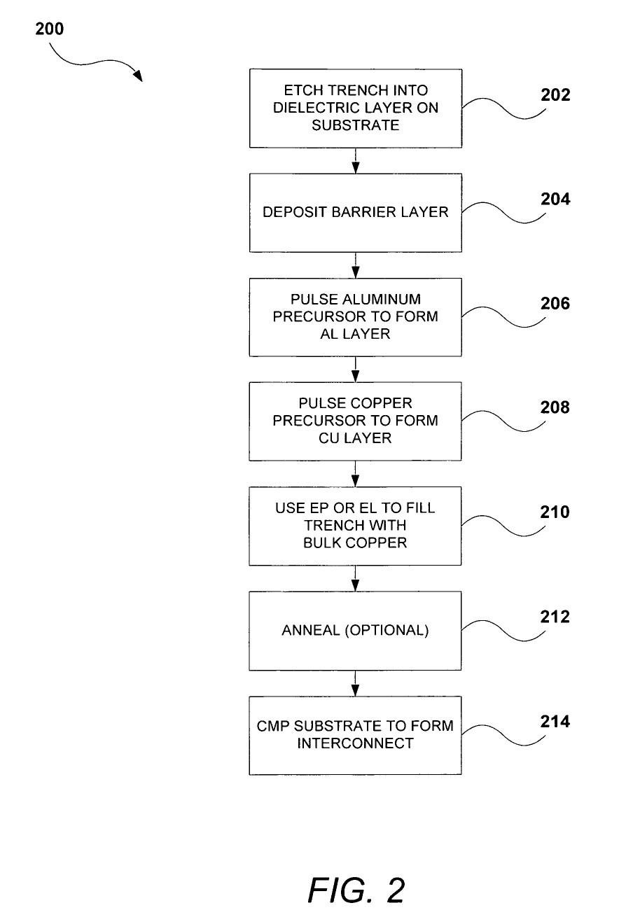

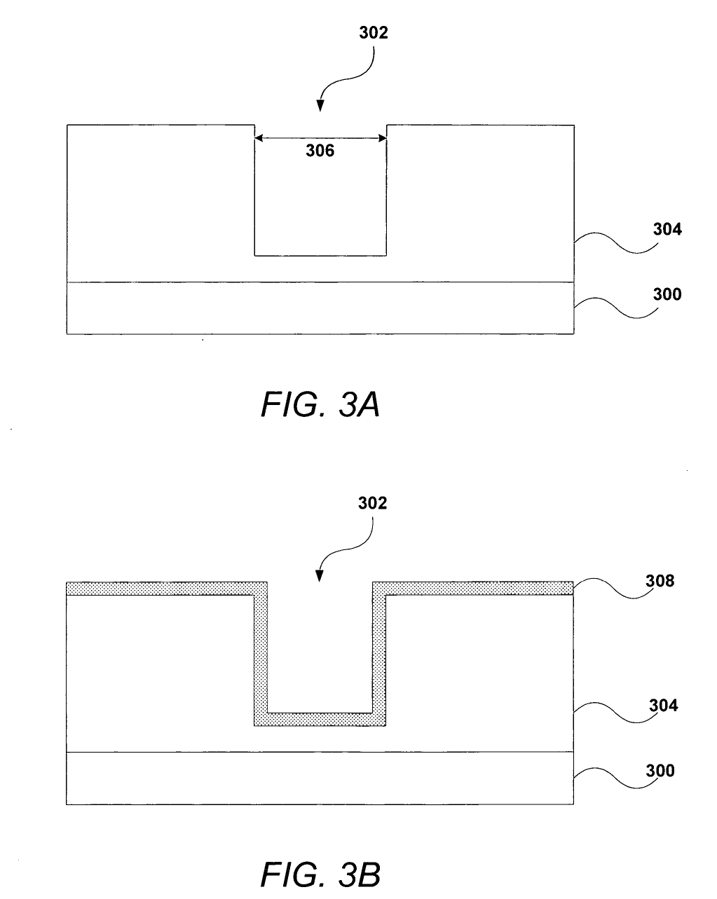

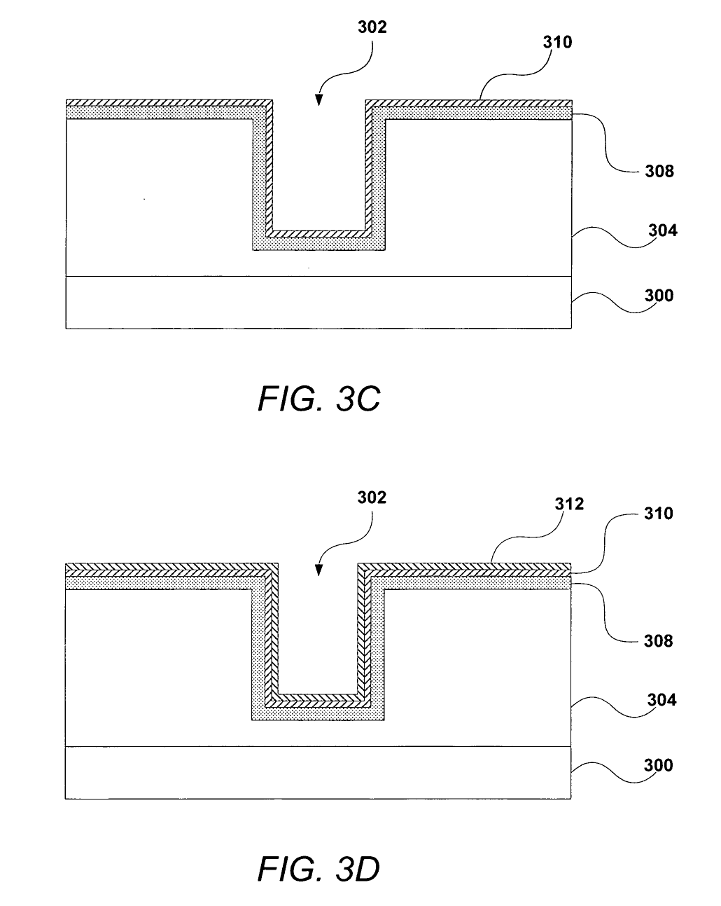

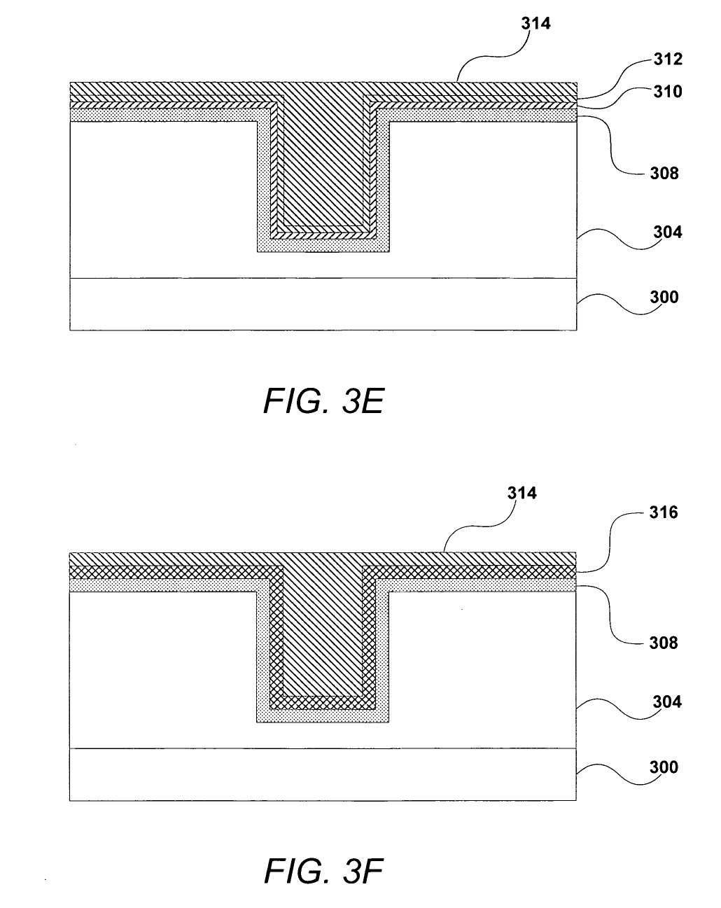

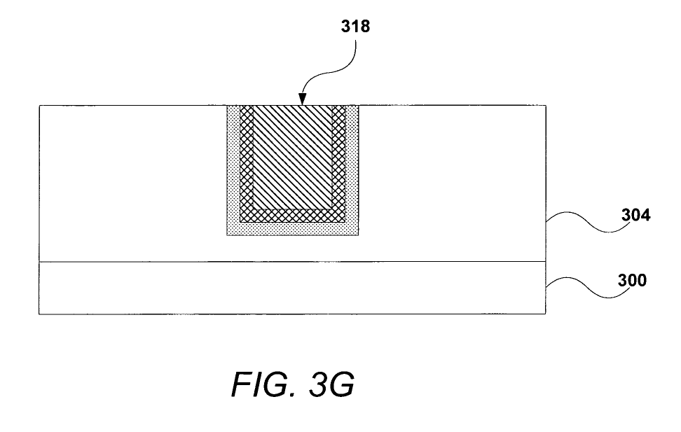

FIG. 2 is a process 200 of forming a copper interconnect in accordance with an implementation of the invention. FIGS. 3A to 3G illustrate various structures that are formed when the process 200 is carried out. For clarity, the structures of FIGS. 3A to 3G will be referenced during the discussion of the process 200 of FIG. 2.

The process 200 begins with the etching of a trench into a dielectric layer for forming copper interconnects on a semiconductor wafer (process 202 of FIG. 2). FIG. 3A illustrates semiconductor wafer 300 that includes at least one trench 302 that has been etched into a dielectric layer 304. The trench 302 has a gap 306 through which metal may enter during a metallization process. The dielectric layer 304 is formed on the semiconductor wafer 300 and provides insulation between electrical components. As semiconductor device dimensions decrease, electrical components such as interconnects must be formed closer together. This increases the capacitance between components with the resulting interference and crosstalk degrading device performance. To reduce the interference and crosstalk, dielectric materials with lower dielectric constants (i.e., low-k dielectric materials) are used to provide insulation between electrical components. Common dielectric materials that may be used in the dielectric layer 304 include, but are not limited to, oxides such as silicon dioxide (SiO₂) and carbon doped oxide (CDO), organic polymers such as perfluorocyclobutane (PFCB), or fluorosilicate glass (FSG).

Conventional photolithography techniques may be used to etch the trench 302 into the dielectric layer 304. As is well known in the art, one photolithography technique includes depositing a photoresist material onto the dielectric layer 304, exposing the photoresist material to ultraviolet radiation using a patterned mask, developing the photoresist material, etching the dielectric layer 304, and removing the photoresist material. The photoresist material that remains after development functions as a mask to allow only selected portions of the dielectric layer 304 to be etched, thereby forming structures such as the trench 302.

Next, a tantalum (Ta) based barrier layer may be deposited into the trench (process 204 of FIG. 2). The barrier layer is generally formed using a material such as tantalum nitride (TaN), tantalum carbide (TaC), or a combination of TaN and TaC and prevents copper metal from diffusing into the dielectric layer, which would likely reduce performance of the interconnect and may lead to electrical shorts. In an implementation of the invention, an ALD process may be carried out within a reaction chamber to deposit the barrier layer. For instance, the semiconductor wafer may be placed in a reaction chamber and barrier layer precursors (i.e., precursors containing tantalum and nitrogen or carbon) may be pulsed into the reaction chamber with appropriate co-reactants and under appropriate ALD process conditions to react and form a TaN or TaC barrier layer. FIG. 3B illustrates the trench 302 after a barrier layer 308 has been deposited.

After the barrier layer is deposited, an ALD process or a CVD process may be used to deposit an aluminum layer onto the barrier layer. The same reaction chamber used to form the barrier layer may be used to form the aluminum layer. In accordance with an implementation of the invention, the aluminum ALD or CVD process may introduce one or more aluminum precursors into the reaction chamber that react to deposit a conformal aluminum layer (process 206 of FIG. 2). One or more co-reactants may also be pulsed into the reaction chamber to react with the aluminum precursor and form the aluminum layer. FIG. 3C illustrates the trench 302 after an aluminum layer 310 has been formed on the barrier layer 308.

In implementations of the invention, the aluminum precursors used in the reaction chamber to form the aluminum layer may include, but are not limited to, aluminum s-butoxide, trimethylaluminum (AlMe₃ or TMA), triethylaluminum (AlEt₃ or TEA), di-i-butylaluminum chloride, di-i-butylaluminum hydride, diethylaluminum chloride, tri-i-butylaluminum, triethyl (tri-sec-butoxy) dialuminum, methylpyrrolidine alane, as well as related derivatives and or precursors of the above.

In implementations of the invention, the ALD or CVD process for the aluminum layer may include the use of one or more co-reactants with the aluminum precursor. The one or more co-reactants may consist of any of a variety of conventional co-reactants for aluminum deposition, including but not limited to hydrogen (H₂), H₂ plasma, NH₃, silane (SiH₄), diborane(B₂H₆), forming gas (e.g., 5% H₂ in N₂), argon (Ar) plasma, helium (He) plasma, and mixtures thereof.

Conventional process parameters may be used for the aluminum layer ALD or CVD process within the reaction chamber. In implementations, the process parameters for the aluminum deposition may include precursor temperatures that range from around 50° C. to around 300° C., substrate temperatures that range from around 50° C. to around 250° C., chamber pressures that range from around 0.01 Torr to around 10 Torr, precursor flow rates that range up to 10 standard liters per minute (SLM), pulse durations that range from 0.1 seconds to 60 seconds, purge durations that range from 0.1 seconds to 60 seconds, and purge or carrier gases that consist of inert gases such as He, N_{2,} or forming gas. In an implementation of the invention, the process conditions for CVD of aluminum may be 150 mTorr with a substrate temperature of 250° C. In other implementations, process parameters different from these may be used. It should be noted that the scope of the invention includes any possible set of process parameters that may be used to carry out the implementations of the invention described herein.

After the aluminum layer is deposited, another ALD or CVD process may be performed to deposit a copper layer onto the aluminum layer. The same reaction chamber used to form the aluminum layer may be used to form the copper layer. In accordance with an implementation of the invention, the copper ALD or CVD process may introduce one or more copper precursors into the reaction chamber that react to deposit a conformal copper layer (process 208 of FIG. 2). One or more co-reactants may also be pulsed into the reaction chamber to react with the copper precursor and form the copper layer. FIG. 3D illustrates the trench 302 after a copper layer 312 has been formed on the aluminum layer 310.

In implementations of the invention, the copper precursors used in the reaction chamber to form the copper layer may include, but are not limited to, bis(N,N′-di-sec-butylacetamidinato)Cu, bis(N,N′-di-isopropylacetamidinato)Cu, bis(N,N′-di-isopropyldimethylaminoacetamidinato)Cu, (VTMS)Cu(I)β-diketiminate (where VTMS=vinyltrimethylsilane), (VTMS)Cu(I)amidinates, methoxypropylamidinates, Cu(II)dimethylaminoethoxide, Cu(II)bis(2,2,6,6-tetramethyl-3,5-heptanedionate), Cu(II)bis(2,2-dimethyl-3,5-heptanedionate), Cu(II)bis(2,2-dimethylhexanedionate), Cu(II)bis(acetylacetonate), Cu(II)bis(hexafluoroacetylacetate), Cu-methyl(trimethyl)acetyl-thioacetate, Cu-methylthiocarboxylate triphenylphosphine, Cu(I)hexamethyldisilazane, CuI, CuBr₂, CuBr, CuCl, CuI₂, Cp-Cu(I)-triethylphosphine (where Cp=cyclopentadienyl), Cp-Cu(I)-trimethylphosphine, Cp-Cu(I)triphenylphosphine, Cu(I)tert-butoxide tetramer, RCpCu(^{t}BuNC) (where ^{t}BuNC=tertbutylisonitrile and R=hydrogen or alkyl substituents such as methyl, ethyl, isopropyl), RCpCu(^{t}BuNC), RCpCu(CO), RCpCu(VTMS), Cu(II)methoxide, Cu(II)bis(dimethyldithiocarbamate), Cu(II)bis(diethyldithiocarbamate), Cu(II)bis(diisobutyldithiocarbamate), Cu(II)bis(methyl-butyl-dithiocarbamate), Cu(II)bis(methylhexyldithiocarbamate), Cu(II)ethoxide, Cu(II)dimethylaminoethoxide, Cu(I)hfac-VTMS (where hfac=hexafluoroacetylacetonate), Cu(II)(1-phenyl-1,3-butanedione)₂, Cu(II)(1-(2-thienyl)-1,3-butanedione)₂, Cu(II)(1,3-(2-thienyl)-1,3-propanedione)₂, Cu(acac)₂ (where acac=acetylacetonato), and Cu(thd)₂ (where thd=tetrahydrodionato).

In implementations of the invention, the deposition process for the copper layer may include the use of one or more co-reactants with the copper precursor. The one or more co-reactants may consist of any of a variety of conventional co-reactants for copper deposition, including but not limited to H₂, H₂ plasma, NH₃, silane, B₂H₆, forming gas, and mixtures thereof. In yet another implementation, the aluminum precursor can be used as a co-reactant for the deposition of the copper precursor. Furthermore, the aluminum precursor can be used in alternating layers, forming a Cu/Al nanolaminate with equal or varying Cu and Al thicknesses.

Conventional process parameters may be used for the copper layer ALD or CVD process within the reaction chamber. In implementations, the process parameters for the copper deposition process may include precursor temperatures that range from around 25° C. to around 250° C., substrate temperatures that range from around 25° C. to around 250° C., chamber pressures that range from around 0.01 Torr to around 10 Torr, precursor flow rates that range up to 10 standard liters per minute (SLM), pulse durations that range from 0.1 seconds to 60 seconds, purge durations that range from 0.1 seconds to 60 seconds, and purge or carrier gases that consist of inert gases such as helium (He), N₂, or forming gas. In other implementations, process parameters different from these may be used. It should be noted that the scope of the invention includes any possible set of process parameters that may be used to carry out the implementations of the invention described herein.

A bulk copper layer is then deposited over the copper and aluminum layers to fill the trench with a bulk copper layer (process 210 of FIG. 2). Generally, an electroplating process or an electroless plating process is used to deposit the bulk copper layer. The bulk copper metal enters the trench through the gap where, due to the relatively larger width of the gap, issues such as trench overhang are reduced or eliminated. The previously deposited copper layer provides a surface upon which the bulk copper metal can nucleate. FIG. 3E illustrates the filling of the trench 302 by a bulk copper layer 314 that has been deposited on the copper layer 312 using an electroplating process or an electroless plating process.

Next, an optional annealing process may be performed to cause the aluminum layer and the copper layer to combine into a Cu—Al alloy layer (process 212 of FIG. 2). The annealing process may be a normal annealing process or a rapid-thermal annealing process. In some implementations, the temperature for the annealing process may range from 50° C. to 400° C. The duration of the annealing process may range from 5 seconds to 120 minutes. FIG. 3F illustrates a Cu—Al alloy layer 316 that is generated by annealing the aluminum layer 310 and the copper layer 312. It should be noted that implementations of the invention may be carried out without an annealing process. The structure may then include distinct layers of barrier 308, aluminum 310, copper 312, and bulk copper 314 with some intermixing at the interfaces but no direct Cu—Al alloy phase formation, as shown in FIG. 3E.

Finally, a chemical mechanical polishing (CMP) process may be used to planarize the deposited copper metal and form the final metal interconnect structure (process 214 of FIG. 2). FIG. 3G illustrates the formation of a metal interconnect 318 after the CMP process is used to planarize the deposited bulk copper layer 314, as well as portions of the Cu—Al alloy layer 316 and the barrier layer 308.

As demonstrated by FIG. 2, in implementations of the invention, ALD processes may be used to form the barrier layer and the Cu—Al alloy layer. This allows one reaction chamber to be used for multiple deposition processes, thereby improving throughput time, decreasing wafer handling requirements and contamination risks, and decreasing the number of processing tools and cost required. In addition, the use of ALD processes for all of these layers results in thinner barriers with larger copper line volume and lower RC delay.

In an alternate implementation of the invention, the above method of FIG. 2 may omit the need for an aluminum layer between the barrier layer and the copper layer. For instance, in an implementation, the Ta-based barrier layer may be co-deposited with aluminum metal. The TaN or TaC barrier layer may be deposited using co-pulses of an aluminum precursor material that react and create an aluminum-rich barrier layer. Such a layer may improve copper adhesion and enable a pure copper layer or a Cu—Al alloy layer to be deposited directly on the Ta-based barrier layer that has been enriched with aluminum.

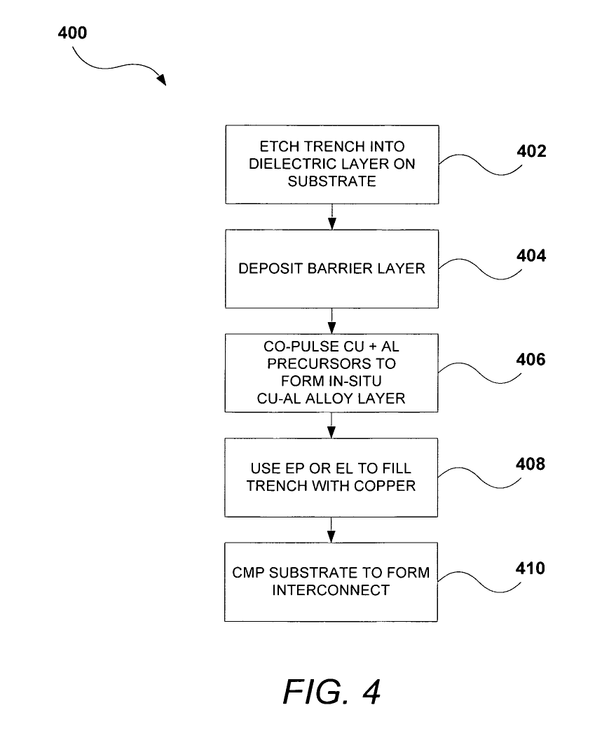

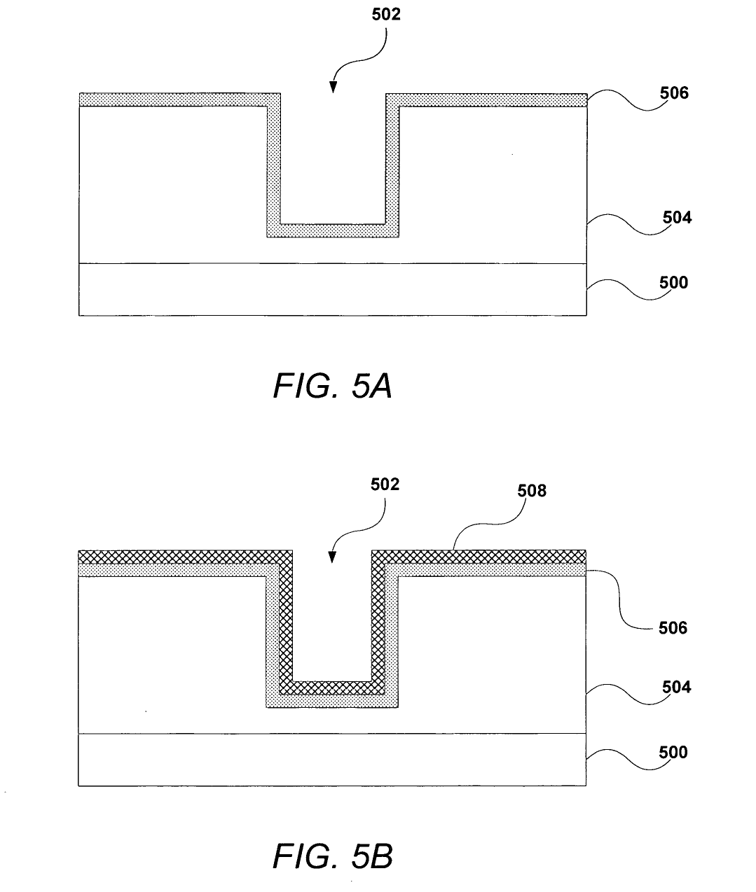

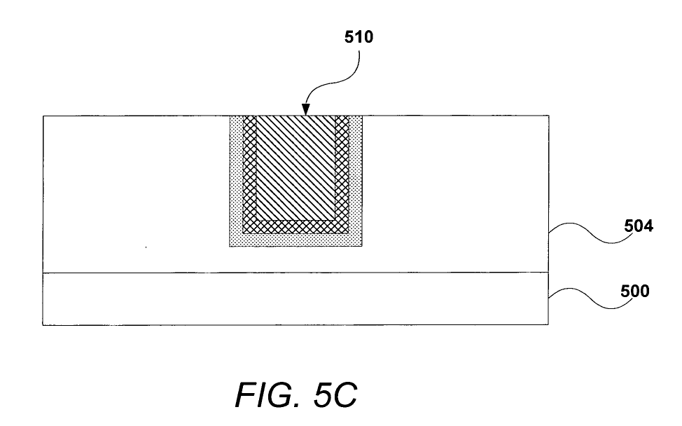

FIG. 4 is a process 400 for forming a copper interconnect in accordance with yet another implementation of the invention. FIGS. 5A to 5C illustrate various structures that are formed when the process 400 is carried out. For clarity, the structures of FIGS. 5A to 5C will be referenced during the discussion of the process 400 of FIG. 4.

Similar to the process 200, the process 400 includes etching a trench into a dielectric layer (process 402 of FIG. 4) and depositing a barrier layer into the trench (process 404 of FIG. 4). The barrier layer is generally formed using a material such as TaN or TaC. Again, an ALD process may be carried out within a reaction chamber to deposit the barrier layer. FIG. 5A illustrates a semiconductor wafer 500 that includes at least one trench 502 that has been etched into a dielectric layer 504 and a barrier layer 506 that has been deposited within the trench 502.

After the barrier layer is deposited, in accordance with this implementation of the invention, an ALD or CVD process may be used to co-deposit aluminum and copper to form an in-situ Cu—Al alloy layer on the barrier layer (process 406 of FIG. 4). The same reaction chamber used to form the barrier layer may be used to form the Cu—Al alloy layer. FIG. 5B illustrates a Cu—Al alloy layer 508 that has been formed in-situ on the barrier layer 506.

The co-deposition of aluminum and copper may occur by co-pulsing aluminum precursors and copper precursors into the reaction chamber. The aluminum precursors and copper precursors may be co-pulsed in a simultaneous manner or in an alternating manner. Furthermore, the pulses of each precursor need not be equal. For instance, multiple pulses of the copper precursor may be delivered in between the aluminum pulses. Flow rates of the aluminum and copper precursor may also be adjusted during deposition. This enables any desired concentration of aluminum in copper to be generated. In implementations of the invention, the above-mentioned aluminum precursors and copper precursors may be used to form the in-situ Cu—Al alloy layer, and the above mentioned process conditions and parameters may be implemented.

In implementations of the invention, the ALD or CVD process for the Cu—Al alloy layer may include the use of one or more co-reactants with the precursors. The one or more co-reactants may consist of any of a variety of conventional co-reactants for aluminum deposition, including but not limited to H₂, H₂ plasma, NH₃, silane, B₂H₆, Ar plasma, He plasma, N₂ plasma, forming gas, and mixtures thereof.

Conventional process parameters may be used for the in-situ Cu—Al alloy deposition within the reaction chamber. In implementations, the process parameters for the aluminum and copper co-deposition may include precursor temperatures that range from around 25° C. to around 250° C., substrate temperatures that range from around 25° C. to around 250° C., chamber pressures that range from around 0.01 Torr to around 10 Torr, precursor flow rates that range up to 10 standard liters per minute (SLM), pulse durations that range from 0.1 seconds to 60 seconds, purge durations that range from 0.1 seconds to 60 seconds, and purge or carrier gases that consist of inert gases such as helium (He), N₂, or forming gas. In other implementations, process parameters different from these may be used. It should be noted that the scope of the invention includes any possible set of process parameters that may be used to carry out the implementations of the invention described herein.

Finally, a bulk copper layer may be deposited over the Cu—Al alloy layer to fill the trench with copper (process 408 of FIG. 4) and a CMP process may be used to planarize and remove excess metal and complete the formation of the metal interconnect (process 410 of FIG. 4). Again, an electroplating process or an electroless plating process may be used to deposit the bulk copper layer. FIG. 5C illustrates a completed metal interconnect 510 formed within the trench 502.

As will be understood by those of ordinary skill in the art, process parameters such as precursor temperature, substrate temperature, chamber pressure, precursor concentrations, precursor flow rates, pulse durations, and purging cycles may vary over a wide range of values based on numerous factors. These factors include, but are not limited to, the needs of a particular process, the desired thickness of each of the layers formed, the interconnect properties desired, the specific precursors chosen, the specific metal chosen for the interconnect, the specific catalyst chosen, the specific co-reactants chosen, the type of reaction chamber that is used, and the specific tools that are used to carry out the ALD process.

Implementations of the invention therefore provide ALD processes for generating a Cu—Al alloy layer that replaces a conventional adhesion layer. The use of a Cu—Al alloy layer in lieu of a Ta or Ru adhesion layer provides a metal interconnect with lower electrical resistance due to higher copper metal content. The copper metal is now in direct contact with the barrier layer. The use of a Cu—Al alloy layer also eliminates the need for a separate copper seed layer so the aspect ratio of the feature to be filled is lower because the gap available for metallization is larger. The use of an ALD process further lowers the aspect ratio of the feature due to the conformal nature of layers formed using ALD.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An apparatus comprising:
a dielectric layer having a trench;
a barrier layer formed on the dielectric layer within the trench;
a Cu—Al alloy layer formed on the barrier layer within the trench; and
a copper layer formed on the Cu—Al alloy layer.

2. The apparatus of claim 1, wherein the dielectric layer comprises at least one of SiO₂, CDO, PFCB, and FSG.

3. The apparatus of claim 1, wherein the trench is formed using photolithography.

4. The apparatus of claim 1, wherein the barrier layer comprises at least one of TaN and TaC.

5. The apparatus of claim 1, wherein the Cu—Al alloy is formed using a pulsed ALD process to co-deposit aluminum metal and copper metal.

6. The apparatus of claim 1, wherein the Cu—Al alloy is formed using a pulsed CVD process to co-deposit aluminum metal and copper metal.

7. The apparatus of claim 1, wherein the Cu—Al alloy is formed using an ALD process to sequentially deposit aluminum metal and copper metal followed by an annealing process to form the Cu—Al alloy.

8. The apparatus of claim 1, wherein the Cu—Al alloy is formed using a CVD process to sequentially deposit aluminum metal and copper metal followed by an annealing process to form the Cu—Al alloy.

9. The apparatus of claim 1, wherein the copper layer is formed using an EP process.

10. The apparatus of claim 1, wherein the copper layer is formed using an EL process.

11. A method comprising:
providing a dielectric layer having a trench on a substrate;
conformally depositing a barrier layer within the trench;
conformally depositing an aluminum layer atop the barrier layer;
conformally depositing a copper layer atop the aluminum layer;
depositing a bulk copper layer atop the copper layer; and
planarizing at least a portion of the bulk copper layer, the copper layer, the aluminum layer, and the barrier layer to form a metal interconnect.

12. The method of claim 11, wherein the barrier layer comprises TaN or TaC.

13. The method of claim 11, wherein the conformally depositing of the aluminum layer comprises using a pulsed CVD deposition process to pulse an aluminum precursor proximate to the trench to form a conformal aluminum layer.

14. The method of claim 13, wherein the pulsed CVD deposition process comprises an ALD process.

15. The method of claim 13, wherein the aluminum precursor comprises aluminum s-butoxide, trimethylaluminum (AlMe₃ or TMA), triethylaluminum (AlEt₃ or TEA), di-i-butylaluminum chloride, di-i-butylaluminum hydride, diethylaluminum chloride, tri-i-butylaluminum, triethyl(tri-sec-butoxy)dialuminum, methylpyrrolidine alane, related derivatives of the above, or precursors of the above.

16. The method of claim 13, wherein the pulsed CVD deposition process includes at least one co-reactant, wherein the co-reactant comprises H₂, H₂ plasma, NH₃, silane, B₂H₆, N₂ plasma, forming gas, Ar plasma, He plasma, or mixtures thereof.

17. The method of claim 11, wherein the conformally depositing of the copper layer comprises using a pulsed CVD deposition process to pulse a copper precursor proximate to the trench to form a conformal copper layer.

18. The method of claim 17, wherein the pulsed CVD deposition process comprises an ALD process.

19. The method of claim 17, wherein the copper precursor comprises bis(N,N′-di-sec-butylacetamidinato)Cu, bis(N,N′-di-isopropylacetamidinato)Cu, bis(N,N′-di-isopropyldimethylaminoacetamidinato)Cu, (VTMS)Cu(I)β-diketiminate (where VTMS=vinyltrimethylsilane), (VTMS)Cu(I)amidinates, methoxypropylamidinates, Cu(II)dimethylaminoethoxide, Cu(II)bis(2,2,6,6-tetramethyl-3,5-heptanedionate), Cu(II)bis(2,2-dimethyl-3,5-heptanedionate), Cu(II)bis(2,2-dimethylhexanedionate), Cu(II)bis(acetylacetonate), Cu(II)bis(hexafluoroacetylacetate), Cu-methyl(trimethyl)acetyl-thioacetate, Cu-methylthiocarboxylate triphenylphosphine, Cu(I)hexamethyldisilazane, CuI, CuBr₂, CuBr, CuCl, CuI₂, Cp-Cu(I)-triethylphosphine (where Cp=cyclopentadienyl), Cp-Cu(I)-trimethylphosphine, Cp-Cu(I)triphenylphosphine, Cu(I)tert-butoxide tetramer, RCpCu(^{t}BuNC) (where ^{t}BuNC=tertbutylisonitrile and R=hydrogen or alkyl substituents such as methyl, ethyl, isopropyl), RCpCu(^{t}BuNC), RCpCu(CO), RCpCu(VTMS), Cu(II)methoxide, Cu(II)bis(dimethyldithiocarbamate), Cu(II)bis(diethyldithiocarbamate), Cu(II)bis(diisobutyldithiocarbamate), Cu(II)bis(methyl-butyl-dithiocarbamate), Cu(II)bis(methylhexyldithiocarbamate), Cu(II)ethoxide, Cu(II)dimethylaminoethoxide, Cu(I)hfac-VTMS (where hfac=hexafluoroacetylacetonate), Cu(II)(1-phenyl-1,3-butanedione)₂, Cu(II)(1-(2-thienyl)-1,3-butanedione)₂, Cu(I)(1,3-(2-thienyl)-1,3-propanedione)₂, Cu(acac)₂ (where acac=acetylacetonato), or Cu(thd)₂ (where thd=tetrahydrodionato).

20. The method of claim 17, wherein the pulsed CVD deposition process includes at least one co-reactant, wherein the co-reactant comprises H₂, H₂ plasma, NH₃, silane, B₂H₆, N₂ plasma, forming gas, or mixtures thereof.

21. The method of claim 11, wherein the depositing of the bulk copper layer comprises using an EP process or an EL process to deposit the bulk copper layer.

22. The method of claim 11, further comprising annealing the aluminum layer and the copper layer to form a copper-aluminum alloy layer.

23. The method of claim 22, wherein the annealing occurs at a temperature between around 50° C. and 400° C. for a time between around 5 seconds and 120 minutes.

24. A method comprising:
providing a dielectric layer on a substrate within a reaction chamber, wherein the dielectric layer includes a trench;
conformally depositing a barrier layer on the dielectric layer within the trench;
conformally depositing an in-situ Cu—Al alloy layer on the barrier layer within the trench;
depositing a copper layer to fill the trench; and
planarizing the copper layer to form the metal interconnect.

25. The method of claim 24, wherein the conformally depositing of the in-situ Cu—Al alloy layer comprises pulsing an aluminum precursor and pulsing a copper precursor into the reaction chamber to react and form the Cu—Al alloy layer.

26. The method of claim 25, wherein the aluminum precursor and the copper precursor are pulsed into the reaction chamber in a simultaneous manner, and wherein a desired concentration of aluminum in copper is generated within the Cu—Al alloy layer by adjusting flow rates for each of the copper precursor and the aluminum precursor.

27. The method of claim 25, wherein the aluminum precursor and the copper precursor are pulsed into the reaction chamber in an alternating manner, and wherein a desired concentration of aluminum in copper is generated within the Cu—Al alloy layer by adjusting the number of copper precursor pulses and the number of aluminum precursor pulses.

28. The method of claim 25, wherein at least one co-reactant is pulsed into the reaction chamber with the aluminum precursor and the copper precursor, and wherein the at least one co-reactant comprises H₂, H₂ plasma, NH₃, silane, B₂H₆, Ar plasma, He plasma, N₂ plasma, forming gas, or mixtures thereof.

29. The method of claim 25, wherein the aluminum precursor comprises aluminum s-butoxide, trimethylaluminum (AlMe₃ or TMA), triethylaluminum (AlEt₃ or TEA), di-i-butylaluminum chloride, di-i-butylaluminum hydride, diethylaluminum chloride, tri-i-butylaluminum, triethyl (tri-sec-butoxy) dialuminum, methylpyrrolidine alane, related derivatives of the above, or precursors of the above.

30. The method of claim 25, wherein the copper precursor comprises bis(N,N′-di-sec-butylacetamidinato)Cu, bis(N,N′-di-isopropylacetamidinato)Cu, bis(N,N′-di-isopropyldimethylaminoacetamidinato)Cu, (VTMS)Cu(I)P-diketiminate (where VTMS=vinyltrimethylsilane), (VTMS)Cu(I)amidinates, methoxypropylamidinates, Cu(II)dimethylaminoethoxide, Cu(II)bis(2,2,6,6-tetramethyl-3,5-heptanedionate), Cu(II)bis(2,2-dimethyl-3,5-heptanedionate), Cu(II)bis(2,2-dimethylhexanedionate), Cu(II)bis(acetylacetonate), Cu(II)bis(hexafluoroacetylacetate), Cu-methyl(trimethyl)acetyl-thioacetate, Cu-methylthiocarboxylate triphenylphosphine, Cu(I)hexamethyldisilazane, CuI, CuBr₂, CuBr, CuCl, CuI₂, Cp-Cu(I)-triethylphosphine (where Cp=cyclopentadienyl), Cp-Cu(I)-trimethylphosphine, Cp-Cu(I)triphenylphosphine, Cu(I)tert-butoxide tetramer, RCpCu(^{t}BuNC) (where ^{t}BuNC=tertbutylisonitrile and R=hydrogen or alkyl substituents such as methyl, ethyl, isopropyl), RCpCu(^{t}BuNC), RCpCu(CO), RCpCu(VTMS), Cu(II)methoxide, Cu(II)bis(dimethyldithiocarbamate), Cu(II)bis(diethyldithiocarbamate), Cu(II)bis(diisobutyldithiocarbamate), Cu(II)bis(methyl-butyl-dithiocarbamate), Cu(II)bis(methylhexyldithiocarbamate), Cu(II)ethoxide, Cu(II)dimethylaminoethoxide, Cu(I)hfac-VTMS (where hfac=hexafluoroacetylacetonate), Cu(II)(1-phenyl-1,3-butanedione)₂, Cu(II)(1-(2-thienyl)-1,3-butanedione)₂, Cu(II)(1,3-(2-thienyl)-1,3-propanedione)₂, Cu(acac)₂ (where acac=acetylacetonato), or Cu(thd)₂ (where thd=tetrahydrodionato).
